(19) United States
(12) Patent Application Publication
(10) Pub. No.: US 2024/0243208 A1
(43) Pub. Date: Jul. 18, 2024

(54) OPTICAL ELEMENT DEVICE

(71) Applicant: ROHM CO., LTD., Kyoto (JP)

(72) Inventors: Eiji KUWAHARA, Kyoto (JP); Toru HIGUCHI, Kyoto (JP)

(73) Assignee: ROHM CO., LTD., Kyoto (JP)

(21) Appl. No.: 18/405,474

(22) Filed: Jan. 5, 2024

(30) Foreign Application Priority Data
Jan. 13, 2023 (JP) 2023-003644

(51) Int. Cl. H01L 31/0203; H01L 31/0216; H01L 33/44; H01L 33/52

(52) U.S. Cl. CPC H01L 31/0203; H01L 31/02162; H01L 33/44; H01L 33/52

(57) ABSTRACT

The present disclosure provides an optical element device. The optical element device includes: a semiconductor substrate, having a light receiving portion; a coating layer, covering the light receiving portion; and a transparent sealing resin, sealing the semiconductor substrate and the coating layer. The coating layer has a first coating layer surface facing the semiconductor substrate and a second coating layer surface located opposite to the first coating layer surface. The coating layer has a recess formed on the second coating layer surface. The transparent sealing resin contacts at least a portion of an inner peripheral surface of the recess.

### TECHNICAL FIELD

The present disclosure relates to an optical element device.

### BACKGROUND

An optical element device such as an optical sensor is available in the prior art. For example, Japan Patent Publication No. 2021-165671 discloses an optical sensor including a detection unit for detecting light, a filter allowing light to pass through, and a sealing resin sealing the detection unit and the filter.

### PRIOR ART DOCUMENT

### Patent publication

[Patent document 1] Japan Patent Publication No. 2021-165671

### BRIEF DESCRIPTION OF THE DRAWINGS

FIG. 1 is a plan view of an optical element device according to a first embodiment.

FIG. 2 is a cross-sectional view along a line II-II in FIG. 1.

FIG. 3 is a partial enlarged cross-sectional view of a region III in FIG. 2.

FIG. 4 is a partial enlarged cross-sectional view of a variation example of a recess of an optical element device according to the first embodiment.

FIG. 5 is a plan view of a recess of an optical element device according to the first embodiment.

FIG. 6 is a plan view of a variation example of a recess of an optical element device according to the first embodiment.

FIG. 7 is a plan view of a variation example of a recess of an optical element device according to the first embodiment.

FIG. 8 is a plan view of a variation example of a recess of an optical element device according to the first embodiment.

FIG. 9 is a cross-sectional view of an optical element device according to a second embodiment.

### DETAILED DESCRIPTION OF THE EMBODIMENTS

Details of the embodiments of the present disclosure are described below. Moreover, unless otherwise specified, the same or corresponding parts are denoted by the same reference numerals or symbols in the accompanying drawings below, and related description is omitted.

### First Embodiment

### Configuration of Optical Element Device

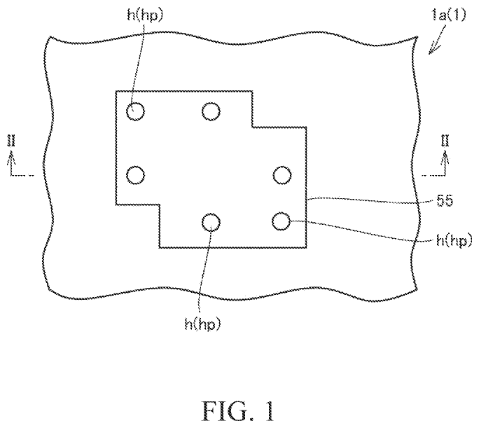

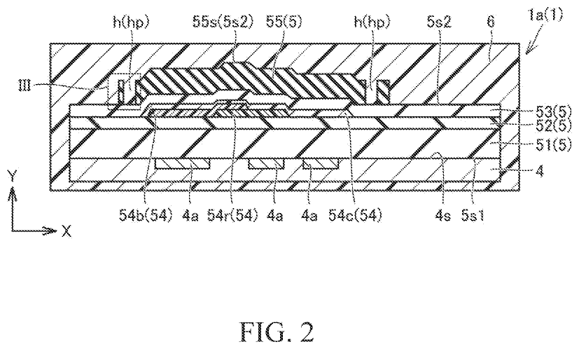

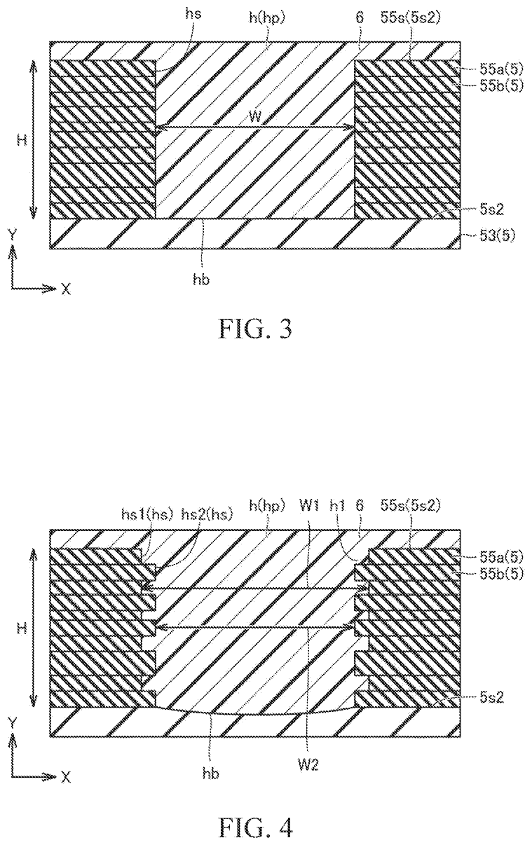

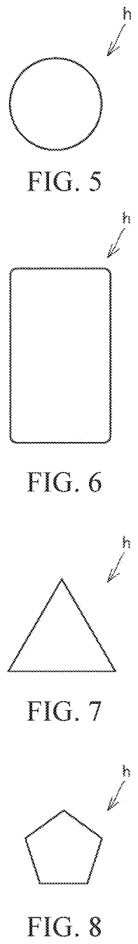

FIG. 1 shows a plan view of an optical element device 1 according to the first embodiment. FIG. 2 shows a cross-sectional view along a line II-II in FIG. 1. FIG. 3 shows a cross-sectional view of a region III in FIG. 2. FIG. 4 shows a partial enlarged cross-sectional view of a variation example of a recess h of the optical element device 1 according to the first embodiment. FIG. 5 shows a plan view of a recess of an optical element device according to the first embodiment.

The optical element device 1 shown in FIG. 1 to FIG. 5 is, for example, an optical sensor 1a that detects light, and primarily includes a semiconductor substrate 4, a coating layer 5 and a transparent sealing resin 6. Moreover, as described below, the optical element device 1 of the present disclosure can also be a light emitting element 1b including a light emitting portion emitting light.

When the optical element device 1 of the first embodiment is implemented by an optical sensor 1a, the coating layer 5 can be formed on the semiconductor substrate 4. The transparent sealing resin 6 seals the semiconductor substrate 4 and the coating layer 5.

The semiconductor substrate 4 is, for example, a Si substrate. The semiconductor substrate 4 has a substrate surface 4s. The substrate surface 4s is an incident surface of light detected by the optical sensor 1a. When the optical element device 1 of the first embodiment is implemented by the optical sensor 1a, the semiconductor substrate 4 has a light receiving portion 4a. The light receiving portion 4a is formed on the substrate surface 4s. As shown in FIG. 1 and FIG. 2, a part of the substrate surface 4s in which the light receiving portion 4a is formed is a light receiving surface of the optical sensor 1a. The light receiving portion 4a detects light passing through the coating layer 5 and incident on the optical sensor 1a.

The light receiving portion 4a can be formed to be one in quantity, or can be formed to be plural in quantity to correspond to the light detected. For example, three light receiving portions 4a can be formed.

The coating layer 5 has a first laminated portion 55, a protection film portion 53, a color filter portion 54, a second laminated portion 52 and a third laminated portion 51. The coating layer 5 is laminated with the first laminated portion 55, the protection film portion 53, the color filter portion 54, the second laminated portion 52 and the third laminated portion 51 sequentially from top to bottom in a Y direction in FIG. 2, for example. That is to say, in a side view of the optical sensor 1a, the first laminated portion 55 in the coating layer 5 is arranged at a position farthest away from the semiconductor substrate 4 in the Y direction. The third laminated portion 51 is connected to the substrate surface 4s, and the third laminated portion 51 in the coating layer 5 is arranged at a position closest to the semiconductor substrate 4 in the Y direction.

The third laminated portion 51 has a first coating layer surface 5s1. The first coating layer surface 5s1 is a surface facing the semiconductor substrate 4. That is to say, the first coating layer surface 5s1 is connected to the substrate surface 4s. The third laminated portion 51 is, for example, an insulating film. The material forming the third laminated portion 51 is, for example, silicon dioxide (SiO₂).

As shown in FIG. 2, when viewing from the third laminated portion 51, the second laminated portion 52 is located opposite to a region in which the semiconductor substrate 4 is arranged in the Y direction. The second laminated portion 52 is, for example, a passivation film. The material forming the second laminated portion 52 is, for example, silicon nitride (SiN).

The color filter portion 54 is connected to the second laminated portion 52. As shown in FIG. 2, when viewing from the second laminated portion 52, the color filter portion 54 is located opposite to the region in which the semiconductor substrate 4 is arranged in the Y direction. For light within a visible range incident on the optical sensor 1a, the color filter portion 54 allows light within a wavelength range corresponding to a predetermined color to pass through. The color filter portion 54 includes, for example, a transparent filter portion 54c, a red filter portion 54r and a blue filter portion 54b. The transparent filter portion 54c allows light within a wavelength range corresponding to all colors in light within a visible range to pass through. The red filter portion 54r allows light within a wavelength range corresponding to red in light within a visible range to pass through. The blue filter portion 54b allows light within a wavelength range corresponding to blue in light within a visible range to pass through. The color filter portion 54 can also include, for example, a color filter portion that allows light within a wavelength range corresponding to other colors to pass through. The material forming the color filter portion 54 is, for example, an epoxy material.

In a plan view viewing the semiconductor substrate 4 from the color filter portion 54, the transparent filter portion 54c, the red filter portion 54r and the blue filter portion 54b are respectively arranged to overlap the light receiving portions 4a. As such, light within a wavelength range corresponding to a predetermined color in light within a visible range incident on the optical sensor 1a can be detected in each of the light receiving portions 4a.

As shown in FIG. 2, the protection film portion 53 is connected to the second laminated portion 52 to cover the color filter portion 54. When viewing from the second laminated portion 52, the protection film portion 53 is located opposite to the region in which the semiconductor substrate 4 is arranged in the Y direction. The protection film portion 53 is a film protecting the color filter portion 54. The material forming the protection film portion 53 is, for example, SiO₂.

As shown in FIG. 2, the first laminated portion 55 is connected to the protection film portion 53. When viewing from the protection film portion 53, the first laminated portion 55 is located opposite to the region in which the semiconductor substrate 4 is arranged in the Y direction. The protection film portion 53 and the first laminated portion 55 have a second coating layer surface 5s2. That is to say, when viewing from the protection film portion 53, the second coating layer surface 5s2 is a surface of the protection film portion 53 and the first laminated portion 55 located opposite to the first coating layer surface 5s1 in the Y direction.

The first laminated portion 55 is formed by laminating a plurality of oxide film layers having different refractive indices to block light in infrared and ultraviolet wavelength ranges. As shown in FIG. 3, in the first embodiment, the first laminated portion 55 is formed by alternately laminating a first oxide film layer 55a and a second oxide film layer 55b in the Y direction. The refractive index of the first oxide film layer 55a is different from the refractive index of the second oxide film layer 55b. The materials forming the first oxide film layer 55a and the second oxide film layer 55b are appropriately determined according to optical characteristics needed by the first laminated portion 55. As such, the first laminated portion 55 allows light within a visible range in light incident on the optical sensor 1a to pass through, and blocks light within infrared and ultraviolet wavelength ranges.

A part of the first laminated portion 55 is formed on the second coating layer surface 5s2 to overlap the light receiving portion 4a in a plan view of the semiconductor substrate 4 viewing from the first laminated portion 55. As such, for light incident on the optical sensor 1a, the first laminated portion 55 allows light within a visible range to pass through, and the light receiving portion 4a can then detect light within a wavelength range corresponding to a predetermined color.

Moreover, the optical element device 1 of the first embodiment is characterized by including a recess h covered by the transparent sealing resin 6, as shown in FIG. 1 to FIG. 4. More specifically, as shown in FIG. 2 and FIG. 3, the recess h is formed on the second coating layer surface 5s2 of the first laminated portion 55. The recess h includes a plurality of recessed portions hp. The transparent sealing resin 6 seals the semiconductor substrate 4 and the coating layer 5 to fill an internal space of the recess h. Since coefficients of thermal expansion of the transparent sealing resin 6 and the coating layer 5 are different, it is possible that the transparent sealing resin 6 strips off from the coating layer 5. In the event of such stripping off, a gap is produced between the transparent sealing resin 6 and the coating layer 5. As a result, there may be changes in characteristics of light detected in the light receiving portion 4a. In the optical element device 1 of the first embodiment, tightness between the transparent sealing resin 6 and the coating layer 5 is improved with the recess h provided at the coating layer 5. As a result, the transparent sealing resin 6 can be prevented from stripping off from the coating layer 5.

As shown in FIG. 1, in a plan view of the semiconductor substrate 4 viewing from the recess h, the recess h is arranged along an outer periphery of the first laminated portion 55. That is to say, the plurality of recessed portions hp are arranged at intervals from one another along the outer periphery of the first laminated portion 55. As shown in FIG. 1 and FIG. 2, a plurality of recesses h may be arranged at opposite positions sandwiching a center of the first laminated portion 55. The recess h is arranged not to overlap the light receiving portion 4a in a plan view of the semiconductor substrate 4 viewing from the recess h. For example, the recess h can also be formed on the second coating layer surface 5s2 of the protection film portion 53. As such, the light receiving portion 4a can detect the light without hindering, by the recess h, the light incident on the light receiving portion 4a.

From the perspective of improving the tightness between the transparent sealing resin 6 and the coating layer 5, the plurality of recessed portions hp are preferably formed as the recess h, as shown in FIG. 1. The number of the recessed portions hp can be, for example, 4. The number of the recessed portions hp can also be, for example, 8. The number of the recessed portions hp can also be, for example, 16.

As shown in FIG. 2 and FIG. 3, the recess h can also pass through the first laminated portion 55. More specifically, the recess h passes through the first laminated portion 55 to be formed from the second coating layer surface 5s2 of the first laminated portion 55 up to the protection film portion 53. As such, an adhesion area between the coating layer 5 and the transparent sealing resin 6 is increased, so that the tightness between the transparent sealing resin 6 and the coating layer 5 can be improved.

As shown in FIG. 3 and FIG. 4, a depth H of the recess h is 1 μm or more. The depth H is a distance from a bottom surface hb of the recess h to the second coating layer surface 5s2 of the first laminated portion 55 in the Y direction. The bottom surface hb in the first embodiment is the second coating layer surface 5s2 of the protection film portion 53. Since the depth H of the recess h is 1 μm or more, the bottom surface hb is not necessarily the second coating layer surface 5s2 of the protection film portion 53. More specifically, the recess h can also pass through in a way other than being formed up to the second coating layer surface 5s2 of the protection film portion 53.

As shown in FIG. 4, the recess h has a stepped portion h1 on an inner peripheral surface hs of the recess h. That is to say, a width W of the recess h in an X direction shown in FIG. 4 is not necessarily consistent with a height direction of the recess h in the Y direction. More specifically, the width W1 can be greater than a width W2. The width W1 is a width W of the recess h in the X direction in a region surrounded by the inner peripheral surface hs1 of the recess h formed by the first oxide film layer 55a. The width W2 is a width W of the recess h in the X direction in a region surrounded by the inner peripheral surface hs2 of the recess h formed by the second oxide film layer 55b. Such stepped portion h1 is formed by, for example, etching performed under a condition that the first oxide film layer 55a is etched preferentially compared to the second oxide film layer 55b. The stepped portion h1 is in contact with the transparent sealing resin 6.

Since the recess h is formed by alternately laminating the plurality of first oxide film layers 55a and second oxide film layers 55b, a plurality of stepped portions h1 can also be formed in the Y direction. By forming the plurality of stepped portions h1, the tightness between the transparent sealing resin 6 and the coating layer 5 can be improved under an anchoring effect.

As shown in FIG. 5, in a plan view of the semiconductor substrate 4 viewing from the recess h, the recess h has a circular shape. In the first embodiment, the width W of the recess h in the X direction shown in FIG. 2 and FIG. 3 is equivalent to an inner diameter of the recess h shown in FIG. 5. The width W of the recess h is 1 μm or more in order to readily fill the recess h with the transparent sealing resin 6.

Moreover, as shown in FIG. 6 to FIG. 8, the recess h can also have a shape different from the shape of the recess h shown in FIG. 5. FIG. 6 to FIG. 8 show plan views of variation examples of the recess h of the optical element device 1 according to the first embodiment. FIG. 6 to FIG. 8 correspond to FIG. 5. The optical element device 1 shown in FIG. 6 to FIG. 8 has basically the same configuration as the optical element device 1 shown in FIG. 1 to FIG. 5, but the recess h has a different shape in a plan view of the semiconductor substrate 4 viewing from the recess h. More specifically, the recess h can have a planar shape as a polygon.

For example, as shown in FIG. 6, the recess h can also have a planar shape as a rectangle. Corners of the rectangle can be rounded. Moreover, as shown in FIG. 7, the recess h can also have a planar shape as a triangle. As shown in FIG. 8, the recess h can also have a planar shape as a pentagon.

### Effects

The optical element device 1 according to the present disclosure includes the semiconductor substrate 4, the coating layer 5 and the transparent sealing resin 6. The semiconductor substrate 4 has the light receiving portion 4a. The coating layer 5 covers the light receiving portion 4a. The transparent sealing resin 6 seals the semiconductor substrate 4 and the coating layer 5. The coating layer 5 has the first coating layer surface 5s1 and the second coating layer surface 5s2. The first coating layer surface 5s1 faces the semiconductor substrate 4. The second coating layer surface 5s2 is located opposite to the first coating layer surface 5s1. The coating layer 5 has the recess h. The recess h is formed on the second coating layer surface 5s2. The transparent sealing resin 6 contacts at least a portion of the inner peripheral surface hs of the recess h. As such, the tightness between the transparent sealing resin 6 and the semiconductor substrate 4 can be improved to thereby prevent the transparent sealing resin 6 from stripping off.

With respect to the optical element device 1, the recess h has the stepped portion h1 on the inner peripheral surface hs. The transparent sealing resin 6 covers the stepped portion h1. As such, the tightness between the transparent sealing resin 6 and the coating layer 5 is improved under an anchoring effect.

With respect to the optical element device 1, the coating layer 5 has the first laminated portion 55 in which a plurality of oxide film layers having different refractive indexes are laminated. A part of the first laminated portion 55 is formed on the second coating layer surface 5s2 to overlap the light receiving portion 4a in a plan view of the semiconductor substrate 4 viewing from the recess h. The recess h is arranged in the first laminated portion 55. As such, the tightness between the transparent sealing resin 6 and the first laminated portion 55 is improved.

With respect to the optical element device 1, in a plan view of the semiconductor substrate 4 viewing from the recess h, the recess h is arranged not to overlap the light receiving portion 4a. As such, the recess h does not hinder light incident on the optical sensor 1a. As a result, the light receiving portion 4a is able to detect the light.

With respect to the optical element device 1, the recess h includes a plurality of recessed portions hp. The plurality of recessed portions hp are arranged to surround the light receiving portion 4a in the plan view of the semiconductor substrate 4 viewing from the recess h. As such, the tightness between the transparent sealing resin 6 and the coating layer 5 is improved.

### Second Embodiment

### Configuration of Optical Element Device

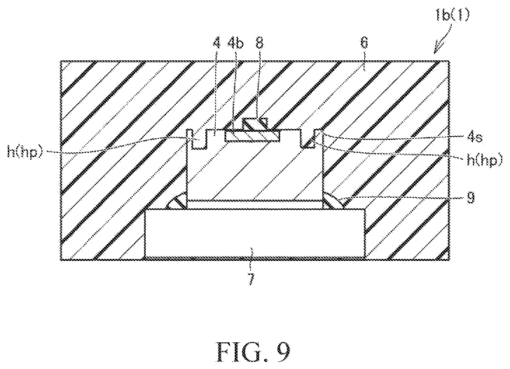

FIG. 9 shows a cross-sectional view of an optical element device 1 according a second embodiment. FIG. 9 corresponds to FIG. 2. The optical element device 1 shown in FIG. 9 has basically the same configuration as the optical element device 1 shown in FIG. 1 to FIG. 4, and differs in that, the optical element device 1 is not the optical sensor 1a but is a light emitting element 1b that emits light. More specifically, as shown in FIG. 9, the semiconductor substrate 4 has a light emitting portion 4b. The light emitting portion 4b is formed on the substrate surface 4s. The recess h is formed on the substrate surface 4s. The recess h includes a plurality of recessed portions hp. The plurality of recessed portions hp are arranged to surround the light emitting portion 4b. Moreover, a coating layer can also be formed in a region not overlapping the light emitting portion 4b on the substrate surface 4s, or the recess h can be formed on the coating layer. That is to say, the optical element device 1 can further include a coating layer. The coating layer can have a first coating layer surface and a second coating layer surface. The first coating layer surface can face the semiconductor substrate 4. The second coating layer surface can be located opposite to the first coating layer surface. The recess h can be formed on the second coating layer surface. The coating layer can also have a first laminated portion in which a plurality of layers having different compositions are laminated. The materials of the plurality of layers can be, for example, oxide layers, nitride layers and nitrogen oxides layers. More specifically, for example, silicon oxide and silicon nitride can be used as the materials for forming the plurality of layers. The recess h can also be formed in the first laminated portion. In this case, the stepped portions shown in FIG. 4 can also be formed on the inner peripheral surface of the recess h by using different end surface positions of the plurality of oxide film layers. A part of the first laminated portion can also be formed on the second coating layer surface to overlap the light emitting portion 4b.

An electrode 8 can also be formed on the substrate surface 4s. The electrode 8 can be arranged to overlap the light emitting portion 4b in the plan view of the semiconductor substrate 4 viewing from the recess h. The light emitting element 1b can emit the light emitted from the light emitting portion 4b from the substrate surface 4s toward the top of FIG. 9.

The semiconductor substrate 4 is mounted on a support body 7 capable of being mounted with the semiconductor substrate 4. The semiconductor substrate 4 is connected to the support body 7 on a surface located opposite to the substrate surface 4s. The semiconductor substrate 4 and the support body 7 can also be bonded to each other by a die bonding material 9.

The transparent sealing resin 6 seals the support body 7, the semiconductor substrate 4 and the recess h. A part of the transparent sealing resin 6 is disposed on an interior of the recess h. As such, even if the optical element device 1 is the light emitting element 1b having the light emitting portion 4b, the tightness between the transparent sealing resin 6 and the semiconductor substrate 4 can also be enhanced as the first embodiment, thereby preventing the transparent sealing resin 6 from stripping off. Moreover, in the optical element device 1 shown in FIG. 9, the optical element device 1 can be used as an optical sensor by forming the light receiving portion 4a shown in FIG. 2 on the semiconductor substrate 4.

### Effects

The optical element device 1 according to the present disclosure includes the semiconductor substrate 4 and the transparent sealing resin 6. The semiconductor substrate 4 has the light emitting portion 4b. The transparent sealing resin 6 seals the semiconductor substrate 4. The semiconductor substrate 4 has the substrate surface 4s. The light emitting portion 4b is formed on the substrate surface 4s. The semiconductor substrate 4 has the recess h. The recess h is formed on the substrate surface 4s. The transparent sealing resin 6 contacts at least a portion of the inner peripheral surface of the recess h. As such, even if the optical element device 1 is the light emitting element 1b having the light emitting portion 4b, the tightness between the transparent sealing resin 6 and the semiconductor substrate 4 can also be improved to thereby prevent the transparent sealing resin 6 from stripping off.

With respect to the optical element device 1, in a plan view of the semiconductor substrate 4 viewing from the recess h, the recess h is arranged not to overlap the light emitting portion 4b. As such, the recess h does not hinder light emitted from the light emitting element 1b. As a result, the light emitting portion 4b is able to reliably emit the light toward an exterior of the transparent sealing resin 6.

It should be understood that all aspects of the disclosed embodiments of the present disclosure are illustrative rather than restrictive. Given that no contradictions are incurred, at least two of the disclosed embodiments above can be combined. The basic scope of the present disclosure is described and represented by way of the claims instead of the description above, and is intended to cover all equivalent meanings and variations made within the scope in accordance with the claims.

Various forms of the present disclosure are summarized in the notes below.

### (Note 1)

An optical element device, comprising:
a semiconductor substrate, having a light receiving portion;
a coating layer, covering the light receiving portion; and
a transparent sealing resin, sealing the semiconductor substrate and the coating layer, wherein
the coating layer has a first coating layer surface facing the semiconductor substrate and a second coating layer surface located opposite to the first coating layer surface,
the coating layer has a recess formed on the second coating layer surface, and
the transparent sealing resin contacts at least a portion of an inner peripheral surface of the recess.

### (Note 2)

The optical element device according to Note 1, wherein the recess has a stepped portion on the inner peripheral surface, and the transparent sealing resin covers the stepped portion.

### (Note 3)

The optical element device according to Note 1 or 2, wherein the coating layer has a first laminated portion in which a plurality of oxide film layers having different refractive indexes are laminated, a part of the first laminated portion is formed on the second coating layer surface to overlap the light receiving portion in a plan view of the semiconductor substrate viewing from the recess, and the recess is formed in the first laminated portion.

### (Note 4)

The optical element device according to any one of Notes 1 to 3, wherein in a plan view of the semiconductor substrate viewing from the recess, the recess is arranged not to overlap the light receiving portion.

### (Note 5)

The optical element device according to Note 4, wherein the recess includes a plurality of recessed portions, and the plurality of recessed portions are arranged to surround the light receiving portion in the plan view of the semiconductor substrate viewing from the recess.

### (Note 6)

An optical element device, comprising:
a semiconductor substrate, having a light receiving portion or a light emitting portion; and
a transparent sealing resin, sealing the semiconductor substrate, wherein
the semiconductor substrate has a substrate surface on which the light receiving portion or the light emitting portion is formed,
the semiconductor substrate has a recess formed on the substrate surface, and
the transparent sealing resin contacts at least a portion of an inner peripheral surface of the recess.

### (Note 7)

The optical element device according to Note 6, wherein in a plan view of the semiconductor substrate viewing from the recess, the recess is arranged not to overlap the light receiving portion or the light emitting portion.

1. An optical element device, comprising:
a semiconductor substrate, having a light receiving portion;
a coating layer, covering the light receiving portion; and
a transparent sealing resin, sealing the semiconductor substrate and the coating layer, wherein
the coating layer has a first coating layer surface facing the semiconductor substrate and a second coating layer surface located opposite to the first coating layer surface,
the coating layer has a recess formed on the second coating layer surface, and
the transparent sealing resin contacts at least a portion of an inner peripheral surface of the recess.

2. The optical element device of claim 1, wherein
the recess has a stepped portion on the inner peripheral surface, and
the transparent sealing resin covers the stepped portion.

3. The optical element device of claim 1, wherein
the coating layer has a first laminated portion in which a plurality of oxide film layers having different refractive indexes are laminated,
a part of the first laminated portion is formed on the second coating layer surface to overlap the light receiving portion in a plan view of the semiconductor substrate viewing from the recess, and
the recess is formed in the first laminated portion.

4. The optical element device of claim 2, wherein
the coating layer has a first laminated portion in which a plurality of oxide film layers having different refractive indexes are laminated,
a part of the first laminated portion is formed on the second coating layer surface to overlap the light receiving portion in a plan view of the semiconductor substrate viewing from the recess, and
the recess is formed in the first laminated portion.

5. The optical element device of claim 1, wherein in a plan view of the semiconductor substrate viewing from the recess, the recess is arranged not to overlap the light receiving portion.

6. The optical element device of claim 2, wherein in a plan view of the semiconductor substrate viewing from the recess, the recess is arranged not to overlap the light receiving portion.

7. The optical element device of claim 5, wherein
the recess includes a plurality of recessed portions, and
the plurality of recessed portions are arranged to surround the light receiving portion in the plan view of the semiconductor substrate viewing from the recess.

8. The optical element device of claim 6, wherein
the recess includes a plurality of recessed portions, and
the plurality of recessed portions are arranged to surround the light receiving portion in the plan view of the semiconductor substrate viewing from the recess.

9. An optical element device, comprising:
a semiconductor substrate, having a light receiving portion or a light emitting portion; and
a transparent sealing resin, sealing the semiconductor substrate, wherein
the semiconductor substrate has a substrate surface on which the light receiving portion or the light emitting portion is formed,
the semiconductor substrate has a recess formed on the substrate surface, and
the transparent sealing resin contacts at least a portion of an inner peripheral surface of the recess.

10. The optical element device of claim 9, wherein in a plan view of the semiconductor substrate viewing from the recess, the recess is arranged not to overlap the light receiving portion or the light emitting portion.
